(19) United States
(12) Patent Application Publication
(10) Pub. No.: US 2012/0103254 A1
(43) Pub. Date: May 3, 2012

(54) THIN-FILM FORMATION SYSTEM AND ORGANIC EL DEVICE MANUFACTURING SYSTEM

(75) Inventor: Tomokazu Sushihara, Mobara-shi (JP)

(73) Assignee: CANON KABUSHIKI KAISHA, Tokyo (JP)

(21) Appl. No.: 13/280,895

(22) Filed: Oct. 25, 2011

(30) Foreign Application Priority Data
Nov. 2, 2010 (JP) 2010-246381

(51) Int. Cl. B05C 13/00; B05C 11/00

(52) U.S. Cl. 118/500

(57) ABSTRACT

Provided is thin-film formation system including: a first conveying mechanism to convey a substrate and a deposition mask to a substrate carry-in position; a second conveying mechanism to convey the substrate and the deposition mask aligned by an alignment mechanism placed at the substrate carry-in position; a film formation mechanism to laminate a layer of organic material on the substrate in a film formation interval of the second conveying mechanism; and a third conveying mechanism to convey the substrate and the deposition mask which have passed the film formation interval from a carry-out position, in which at least one of the first conveying mechanism and the third conveying mechanism is placed parallel to the second conveying mechanism.

### BACKGROUND OF THE INVENTION

1. Field of the Invention

The present invention relates to a thin-film formation system which forms thin films on substrates in a vacuum environment as well as to an in-line manufacturing system for organic electroluminescence (EL) devices, the in-line manufacturing system being equipped with one or more thin-film formation systems as film formation chambers.

2. Description of the Related Art

Recently, organic EL device manufacturing systems capable of mass-producing organic EL devices have been being developed. Since organic EL devices are vulnerable to moisture, manufacture based on dry processes is currently in the mainstream and a vacuum deposition process is used frequently which involves evaporating or sublimating organic material by heating in a vacuum environment and depositing the organic material on a substrate.

Regarding systems for manufacturing organic EL devices, clustered manufacturing systems for organic EL devices are used widely in which a conveying robot designed for use in a vacuum environment is placed in the center and pieces of vacuum deposition apparatus are placed radially around the conveying robot. In the clustered manufacturing systems for organic EL devices, the conveying robot placed in the center conveys substrates in the vacuum environment to the vacuum deposition apparatus. Then, after completion of alignment between deposition masks placed in advance in the vacuum deposition apparatus and the substrates, film formation is started. Consequently, very expensive organic material is consumed even during the time required for the alignment. This reduces usability of the organic material, contributing to increases in manufacturing costs of the organic EL devices as a result.

Given such circumstances, there is demand for a manufacturing system which can effectively use organic material. Thus, for example, an in-line manufacturing system for organic EL devices has been proposed which forms films while conveying substrates and deposition masks successively (see Japanese Patent Application Laid-Open No. 2005-085605).

However, with the organic EL device manufacturing system described in Japanese Patent Application Laid-Open No. 2005-085605, in successively conveying substrates and deposition masks as conveyed bodies, buffer intervals longer than the length of the conveyed bodies are provided to reduce spacing between the conveyed bodies and thereby make succeeding conveyed bodies catch up with the preceding conveyed bodies. Specifically, the distance from travel start position of the conveyed bodies to start position of a film formation interval needs to be at least twice as long as the length of the conveyed bodies when an alignment mechanism and a buffer interval travel mechanism are included. Also, the distance from end position of the film formation interval to travel end position needs to be at least twice as long as the length of the conveyed bodies when the buffer interval travel mechanism and a separation mechanism are included. Therefore, a distance at least four times as long as the length of the conveyed bodies is required around the film formation interval, which increases installation space of the system.

Also, in the case of an organic EL device manufacturing system which allows for a full color coating process, since multiple pieces of vacuum deposition apparatus are placed as described above, it is considered that the installation space of the system will increase markedly. The increase in the system installation space increases the area occupied by a clean room and thereby increases the manufacturing costs of the organic EL devices when investment costs and operating costs of the clean room are included.

### SUMMARY OF THE INVENTION

Thus, an object of the present invention is to provide a thin-film formation system which can reduce the manufacturing costs of EL devices by combining effective use of organic material with reduction of system installation space as well as to provide an in-line manufacturing system for organic EL devices, where the manufacturing system includes the thin-film formation system as a film formation chamber.

To achieve the above object, the present invention is configured as follows.

That is, a thin-film formation system according to the present invention includes: a first conveying mechanism to convey a substrate and a deposition mask to a substrate carry-in position; an alignment mechanism placed at the substrate carry-in position and to align the substrate and the deposition mask with each other by moving the substrate and the deposition mask relatively to each other; a second conveying mechanism to pass the aligned substrate and the deposition mask through a film formation interval; a film formation mechanism to laminate a layer of organic material on the substrate through an opening in the deposition mask in the film formation interval; and a third conveying mechanism to convey from a carry-out position the substrate and the deposition mask which have passed the film formation interval, in which at least one of the first conveying mechanism and the third conveying mechanism is placed parallel to the second conveying mechanism.

According to the present invention, in at least one of a preceding stage and succeeding stage of a film formation mechanism, the conveying mechanism at the substrate carry-in position or carry-out position is placed parallel to the conveying mechanism in the film formation interval. Also, the alignment mechanism is placed at the substrate carry-in position.

This configuration reduces system installation space more than when the conveying mechanism at the substrate carry-in position or carry-out position is placed in series with the conveying mechanism in the film formation interval. Also, the reduction in the system installation space allows the system itself to be downsized, and consequently the system is expected to be reduced in cost. Furthermore, the reduction in the system installation space leads to a reduced clean-room area, thereby allowing reduction in investment costs and running costs of the clean room. This offers the advantage of being able to combine effective use of organic material with reduction of system installation space, and thereby reduce the manufacturing costs of EL devices.

Further features of the present invention will become apparent from the following description of exemplary embodiments with reference to the attached drawings.

### BRIEF DESCRIPTION OF THE DRAWINGS

FIGS. 1A, 1B, 1C and 1D are schematic diagrams showing an embodiment of a thin-film formation system according to the present invention.

FIG. 2 is a plan view showing an in-line manufacturing system for organic EL devices, according to the present embodiment.

FIG. 3 is an explanatory diagram showing a relationship between conveyance time and conveyor speed in a thin-film formation system according to an example.

### DESCRIPTION OF THE EMBODIMENTS

Preferred embodiments of the present invention will now be described in detail in accordance with the accompanying drawings.

An embodiment of the present invention will be described below with reference to the accompanying drawings, but the present invention is not limited to this embodiment. Well-known or publicly known techniques in the art are applied to part which is not specifically illustrated or described herein.

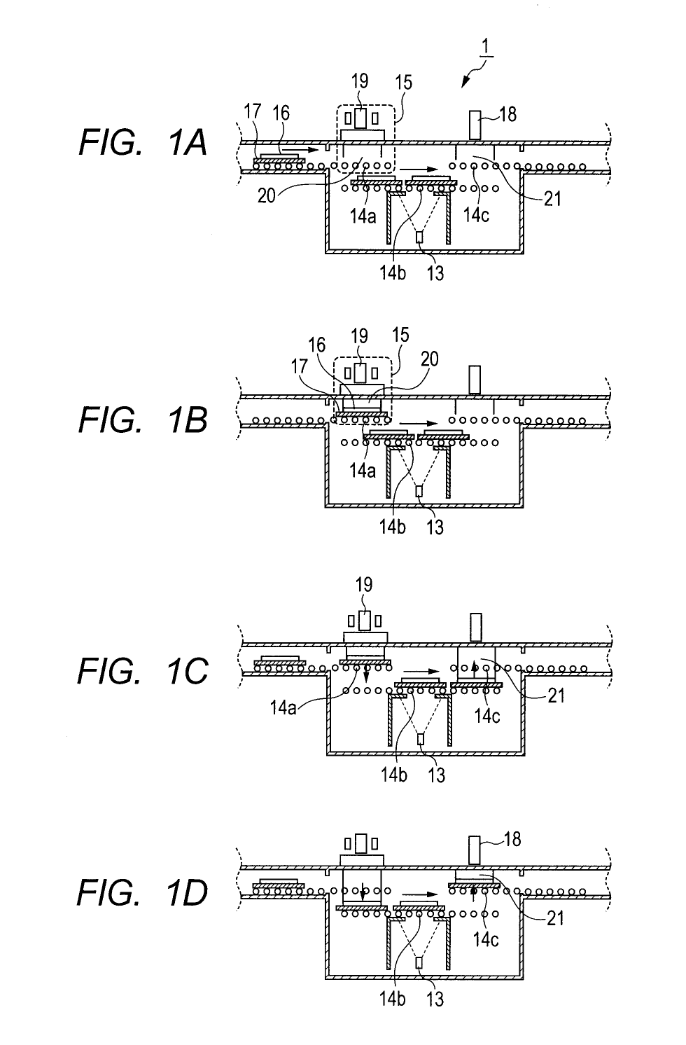

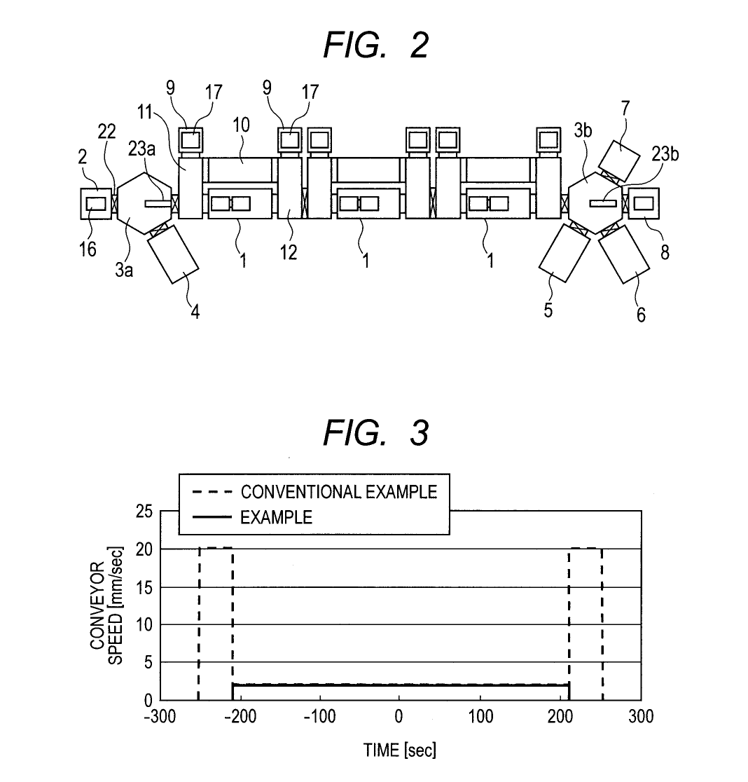

First, an embodiment of an organic EL device manufacturing system according to the present invention will be described with reference to FIGS. 1A to 1D and 2. FIGS. 1A to 1D are schematic diagrams showing an embodiment of a thin-film formation system according to the present invention. FIG. 2 is a plan view showing an in-line manufacturing system for organic EL devices, according to the present embodiment.

<In-Line Manufacturing System for Organic EL Devices>

As shown in FIG. 2, the in-line manufacturing system for organic EL devices according to the present embodiment is designed to laminate layers of organic material while conveying substrates 16 and deposition masks successively in a vacuum environment. In the in-line manufacturing system for organic EL devices according to the present embodiment, a loading chamber 2, a conveying chamber 3a on the upstream side, three film formation chambers 1, a conveying chamber 3b on the downstream side, and an unloading chamber 8 are arranged in series via respective gate valves 22.

The loading chamber 2 is a holding chamber in which the substrates 16 are input first and is equipped with an evacuation mechanism for evacuating the chamber after the substrates 16 are input at atmospheric pressure.

The upstream-side conveying chamber 3a is inserted between the loading chamber 2 and a first-stage film formation chamber 1. Also, a conveying robot 23a designed for use in a vacuum environment is installed in the upstream-side conveying chamber. Furthermore, the conveying chamber 3a is appended with a preprocessing chamber 4 via a gate valve 22, where the preprocessing chamber 4 is to preprocess the substrates 16. In the preprocessing chamber 4 necessary preprocessing such as heat treatment and UV processing is applied to the substrates 16.

The film formation chambers 1 are processing chambers intended to form thin films on substrates. Having an equipment configuration in which the three film formation chambers 1 are arranged in series, the present embodiment is capable of manufacturing full-color organic EL devices. Specifically, for example, layers of R (red), G (green), and B (blue) organic materials are laminated in order in the respective film formation chambers 1. Each film formation chamber 1 includes a mask chamber 9 to hold the deposition masks 17, a fitting chamber 11 to fit the substrate 16 on the deposition mask 17, a separation chamber 12 to separate the substrate 16 from the deposition mask, and a mask return chamber 10 to return the deposition mask 17.

The downstream-side conveying chamber 3b is inserted between a third stage film formation chamber 1 and the unloading chamber 8 to carry out processed substrates. Also, a conveying robot 23b designed for use in a vacuum environment is installed in the conveying chamber 3b. The conveying chamber 3b include an electrode formation chamber 5 to form an electrode on the substrate 16 laminated with organic material, a bonded-substrate loader 7 to input a bonded substrate, and a bonding chamber 6 to bond the bonded substrate to the substrate 16 laminated with organic material. The electrode formation chamber 5 includes a mechanism for forming electrodes and the bonding chamber 6 includes a mechanism for bonding together substrates.

The unloading chamber 8 is a holding chamber to hold processed substrates, and is equipped with an evacuation mechanism for evacuating the chamber after the processed substrates are input at atmospheric pressure.

<Thin-Film Formation System>

A thin-film formation system according to the present embodiment is configured, for example, as a film formation chamber 1 of the in-line manufacturing system for organic EL devices. As shown in FIG. 1A, the film formation chamber 1 includes an alignment mechanism 15, a film formation mechanism 13, a conveying mechanism 14 and lifting mechanisms (transfer mechanisms) 18 and 19. Also, the film formation chamber 1 includes an evacuation mechanism, an inert gas introduction mechanism and a pressure measuring mechanism (which are not shown). The conveying mechanism 14 includes a first conveying mechanism 14a located at a substrate carry-in position 20 and a third conveying mechanism 14c located at a carry-out position 21 in the preceding stage and succeeding stage of the film formation mechanism 13, respectively. Also the conveying mechanism 14 includes a second conveying mechanism 14b placed above or below the film formation mechanism 13, located in the film formation interval, and configured to be able to vary conveyor speed in the preceding stage and succeeding stage of the film formation mechanism 13.

The deposition mask 17 fitted with the substrate is carried into the first conveying mechanism 14a located at the carry-in position 20 in the film formation chamber 1 from the fitting chamber 11.

The alignment mechanism 15 is intended to align the substrate 16 carried into the film formation chamber 1 and the deposition mask 17 supplied from the mask chamber 9 relative to each other. The alignment mechanism 15 according to the present embodiment is placed at the carry-in position 20 of the substrate 16.

The lifting mechanism (transfer mechanism) 19 is intended to transfer the substrate 16 and deposition mask aligned by the alignment mechanism 15 to the second conveying mechanism 14b located in the film formation interval. By attaching the lifting mechanism 19 to the alignment mechanism 15, the configuration of the present embodiment simplifies the system. Thus, the first conveying mechanism 14a located at the substrate carry-in position 20 in the preceding stage of the film formation mechanism 13 is placed parallel to the second conveying mechanism 14b located in the film formation interval. First, the lifting mechanism 19 receives the substrate 16 and deposition mask 17 aligned by the alignment mechanism 15 from the first conveying mechanism 14a. Subsequently, the first conveying mechanism 14a extends wide enough to allow passage of the substrate 16 and deposition mask 17 and moves to such a position as not to interfere with the substrate 16 and deposition mask 17. Next, the lifting mechanism 19 delivers the substrate 16 and deposition mask to the second conveying mechanism 14b. After the delivery, the lifting mechanism 19 and the first conveying mechanism 14a return to the original position to prepare to receive a next substrate. Available delivery methods of the substrate 16 and deposition mask 17 are not limited to this, and include any method which can deliver the substrate 16 and deposition mask 17 from the first conveying mechanism 14a to the second conveying mechanism 14b, for example, by lifting and moving the first conveying mechanism 14a using the lifting mechanism 19.

The film formation mechanism 13 is installed in the film formation interval for the second conveying mechanism 14b, and one or more evaporation sources are lined up in the film formation mechanism 13. According to the present embodiment, since the second conveying mechanism 14b to convey the substrate 16 and deposition mask 17 is placed on the film formation mechanism 13, the evaporation sources are placed facing upward. That is, when the deposition mask 17 fitted with the substrate 16 passes through the film formation interval of the film formation mechanism 13, the organic material is deposited on the substrate 16 through openings in the deposition mask 17.

The lifting mechanism (transfer mechanism) 18 is placed in the succeeding stage of the second conveying mechanism 14b and to transfer the substrate 16 and deposition mask 17 which have passed the film formation interval to the third conveying mechanism 14c located at the carry-out position 21. Thus, the third conveying mechanism 14c located at the carry-out position 21 in the succeeding stage of the film formation mechanism 13 is placed parallel to the second conveying mechanism 14b located in the film formation interval. First, the third conveying mechanism 14c extends wide enough to allow passage of the substrate 16 and deposition mask 17 and moves to such a position as not to interfere with the substrate 16 and deposition mask 17. Subsequently, the lifting mechanism 18 descends and receives the substrate 16 and deposition mask 17 subjected to film formation from the second conveying mechanism 14b. Next, the lifting mechanism 18 ascends to a position where the substrate 16 and deposition mask 17 held by the lifting mechanism 18 will be delivered to the third conveying mechanism 14c. Subsequently, the third conveying mechanism 14c returns to a position where the substrate 16 and deposition mask 17 can be conveyed and receives the substrate 16 and deposition mask 17 from the lifting mechanism 18. However, available delivery methods of the substrate 16 and deposition mask 17 are not limited to this, and include any method which can deliver the substrate 16 and deposition mask 17 from the second conveying mechanism 14b to the third conveying mechanism 14c, for example, by lifting and moving the third conveying mechanism 14c using the lifting mechanism 18.

The separation chamber 12 is placed behind the carry-out position 21 in the film formation chamber 1, and the substrate 16 and deposition mask 17 are conveyed to the separation chamber 12 by the third conveying mechanism 14c.

Next, operation of the in-line manufacturing system for organic EL devices according to the present embodiment will be described. The substrate 16 is input in the organic EL device manufacturing system from the loading chamber 2. The loading chamber 2 is evacuated after the substrate 16 is input at atmospheric pressure.

After the loading chamber 2 is evacuated, the gate valve 22 is opened and the substrate 16 is conveyed to the preprocessing chamber 4 by the conveying robot 23a installed in the conveying chamber 3a. In the preprocessing chamber 4, necessary preprocessing such as heat treatment and UV processing is applied to the substrate 16.

The substrate 16 subjected to preprocessing is conveyed to the fitting chamber 11 again by the conveying robot 23a of the conveying chamber 3a. In the fitting chamber 11, the substrate 16 is fitted on the deposition mask 17. The deposition mask 17 fitted with the substrate is conveyed to the carry-in position 20 in the film formation chamber (thin-film formation system) 1 by the first conveying mechanism 14a.

The substrate 16 and deposition mask 17 conveyed to the film formation chamber 1 are aligned relative to each other by the alignment mechanism 15. A specific alignment process will be described in detail later in the description of an example.

The aligned substrate 16 and deposition mask 17 are transferred by the lifting mechanism 19 to the second conveying mechanism 14b which passes through the film formation interval. The substrate 16 and deposition mask 17 transferred to the second conveying mechanism 14b pass over the film formation mechanism 13 (film formation interval) on which one or more evaporation sources are lined up. Consequently, organic material is deposited on the substrate 16 through the openings in the deposition mask 17 and, for example, an R layer is laminated. The substrate 16 and deposition mask 17 which have passed through the film formation mechanism 13 are transferred to the carry-out position 21 in the film formation chamber 1 by the lifting mechanism 18.

The substrate 16 and deposition mask 17 transferred to the carry-out position 21 in the film formation chamber 1 are conveyed to the separation chamber 12 by the third conveying mechanism 14c and separated into the substrate 16 and deposition mask 17. Only the substrate 16 separated in the separation chamber 12 is conveyed to the next fitting chamber 11. Similarly, for example, a G layer and B layer are laminated in a similar manner.

The substrate 16 on which the RGB organic materials have been deposited is conveyed to the electrode formation chamber 5 by the conveying robot 23b installed in the conveying chamber 3b. In the electrode formation chamber 5, an upper electrode is formed, for example, by sputtering.

The substrate 16 on which the upper electrode has been formed is conveyed to the bonding chamber 6 by the conveying robot 23b in the conveying chamber 3b. In the bonding chamber 6, a bonded substrate input from a bonded-substrate loading chamber 7 is bonded to the substrate 16 laminated with the organic materials.

After the bonding, the substrate 16 is conveyed to the unloading chamber 8 by the conveying robot 23b in the conveying chamber 3b. Then, the unloading chamber 8 is evacuated and the substrate 16 is taken out of the unloading chamber 8 at atmospheric pressure.

As described above, in the organic EL device manufacturing system according to the present embodiment, the first conveying mechanism 14a located at the substrate carry-in position 20 and the third conveying mechanism 14c located at the carry-out position 21 in the preceding stage and succeeding stage of the film formation mechanism 13, respectively, are placed parallel to the second conveying mechanism 14b located in the film formation interval. This reduces system installation space more than when the first conveying mechanism 14a at the substrate carry-in position 20, the second conveying mechanism 14b in the film formation interval, and the third conveying mechanism 14c at the carry-out position 21 are arranged in series with one another. The present invention is not limited to this, and it is sufficient if in at least one of the preceding stage and succeeding stage of the film formation mechanism 13, the first conveying mechanism 14a at the substrate carry-in position 20 or the third conveying mechanism 14c at the carry-out position 21 is placed parallel to the second conveying mechanism 14b located in the film formation interval. According to the present embodiment, the alignment mechanism 15 is placed at the substrate carry-in position 20.

Also, the reduction in the system installation space allows the system itself to be downsized, and consequently the system is expected to be reduced in cost. Furthermore, the reduction in the system installation space leads to a reduced clean-room area, thereby allowing reduction in investment costs and running costs of the clean room. Thus, effective use of organic material can be combined with reduction of system installation space, resulting in reduced manufacturing costs of organic EL devices.

A preferred embodiment of the present invention has been described above, but this is only an example provided for purposes of illustration, and the present invention can be embodied in various forms different from the above embodiment without departing from the spirit of the invention.

For example, even when the substrate is increased in size and set in an upright position, the present invention provides a similar advantage. When productivity improvements resulting from the size increase is taken into consideration, the present invention is effective in achieving further cost reductions.

### EXAMPLE

Next, the present invention will be described in more detail by citing an example of the thin-film formation system according to the present invention. In the present example, a thin-film formation system of the configuration shown in FIGS. 1A to 1D is built and used to study conveyance time. The external dimensions of the substrate 16 and deposition mask 17 used in the present example are 460 mm×720 mm×0.5 mm and 500 mm×800 mm×25 mm, respectively.

First, as shown in FIG. 1A, the substrate 16 is fitted on the deposition mask 17 in the fitting chamber 11 located in the preceding stage of the film formation chamber 1. The substrate 16 and deposition mask 17 fitted together are conveyed to the carry-in position 20 in the film formation chamber 1 by the first conveying mechanism 14a. In the present example, the alignment mechanism 15 is placed at the carry-in position 20. Although the substrate and deposition mask 17 are fitted together in the previous stage of the film formation chamber 1, this is not restrictive, and the substrate 16 and deposition mask 17 may be fitted together, for example, at the carry-in position 20.

Next, as shown in FIG. 1B, the inputted substrate and deposition mask 17 are separated once, and then aligned relative to each other in a noncontact manner by the alignment mechanism 15. Specifically, the alignment mechanism 15 includes an image sensor to recognize alignment marks on the substrate 16 and deposition mask 17 and an image processing mechanism to perform computations on image information inputted from the image sensor. Furthermore, the alignment mechanism 15 includes a moving unit to move the substrate 16 and deposition mask 17 relative to each other based on computational results produced by the image processing mechanism. In the present example, the alignment is performed by moving the substrate 16 with the deposition mask 17 fixed.

After the alignment process is finished, the substrate 16 and deposition mask 17 are brought into close contact with each other. In so doing, the image processing mechanism computes relative position of the substrate 16 and deposition mask 17 again and checks whether an “amount of displacement” is within a prescribed value range. If the amount of displacement is within the prescribed value range, the system proceeds to the next process. If the amount of displacement is out of the prescribed value range, the substrate 16 and deposition mask 17 are separated and the alignment process is performed again.

Next, if the amount of displacement falls within the prescribed value range, the substrate 16 and deposition mask 17 brought into close contact again are transferred to the second conveying mechanism 14b as shown in FIG. 1C when the preceding substrate 16 and deposition mask 17 are detected to be at a desired position by a sensor (not shown). The present example assumes a 7-minute cycle and it is known empirically that the alignment is completed in 3 minute, and thus there is sufficient time, even allowing for carry-in operation of the substrate 16 and deposition mask 17. Consequently, the alignment mechanism 15 has a waiting time after completion of the alignment operation.

For the transfer to the second conveying mechanism 14b which is arranged at underside of gravity direction of the first conveying mechanism 14a and in parallel to the first conveying and mechanism 14a, the lifting mechanism 19 attached to the alignment mechanism 15 is used. A travel distance a little longer than the total thickness of the substrate 16, deposition mask 17 and conveying roller is sufficient for the transfer, and a clearance of 80 mm is sufficient in the present example. The time required to travel a distance of 80 mm is approximately 10 sec. Also, the first conveying mechanism 14a of the alignment mechanism (at the carry-in position 20) is provided with a function to move to such a position as not to interfere with the substrate 16 and deposition mask 17 during transfer. In the present example, by sliding in a direction perpendicular to the conveying direction, the first conveying mechanism 14a moves to such a position as to become wider than the width of the deposition mask 17.

Next, as shown in FIG. 1D, the substrate 16 and deposition mask 17 transferred to the second conveying mechanism 14b are accelerated to a speed necessary for film formation. In the present example, the conveyor speed during film formation is set to 2 mm/sec and the acceleration value during acceleration is set to 20 mm/sec². The time required to accelerate to 2 mm/sec is 0.1 sec. This means that the time required for transfer from the alignment mechanism 15 to the second conveying mechanism 14b is approximately 10 sec, and thus the spacing from the preceding substrate 16 and deposition mask 17 can be set to approximately 20 mm. A film is deposited by the film formation mechanism 13 to a desired film thickness on the substrate 16 and deposition mask 17 accelerated to the film formation speed by the second conveying mechanism 14b.

Although a single layer is illustrated in the present example, multiple layers of film can be formed if multiple evaporation sources are lined up in the traveling direction. The substrate 16 and deposition mask 17 which have gone through film formation stop at a predetermined position. The deceleration value during deceleration is also set to 20 mm/sec². Thus, the time required to decelerate from 2 mm/sec to a stop is 0.1 sec.

FIG. 3 is an explanatory diagram showing a relationship between conveyance time and conveyor speed in the thin-film formation system according to the example, namely a graph showing the conveyor speed for the substrate and deposition mask before and after passage through the film formation mechanism when the time of passage is taken as 0 sec. In a conventional example, the conveyor speed needs to be accelerated to a level equal to or higher than the conveyor speed for film formation to catch up with the preceding substrate 16 and deposition mask 17. If a maximum speed is 20 mm/sec and acceleration is 20 mm/sec², a time of approximately 40 sec is required to catch up with the preceding substrate 16 and deposition mask 17. If the substrate is increased in size, either more time is required or the catch-up speed need to be further increased. In the former case, the time available for alignment is reduced and in the latter case, acceleration and deceleration could cause the aligned substrate 16 and deposition mask 17 to be displaced from each other.

The stopped substrate 16 and deposition mask 17 are transferred by the lifting mechanism 18 to the third conveying mechanism 14c located at the carry-out position 21 in the film formation chamber 1. A clearance of 80 mm is sufficient for the travel distance during ascent and descent and the time required to travel a distance of 80 mm is approximately 10 sec. The substrate 16 and deposition mask 17 transferred to the carry-out position 21 in the film formation chamber 1 are conveyed to the separation chamber 12. Although in the present example, the substrate 16 and deposition mask 17 are separated in the succeeding stage of the film formation chamber 1, the substrate 16 and deposition mask 17 may be separated, for example, at the carry-out position 21 in the film formation chamber 1.

In the present example, the first conveying mechanism 14a located at the substrate carry-in position 20 and the third conveying mechanism 14c located at a carry-out position 21 in the preceding stage and succeeding stage of the film formation mechanism 13, respectively, are placed parallel to the second conveying mechanism 14b located in the film formation interval, thereby allowing reduction in the system installation space. This enables combining effective use of organic material with reduction of system installation space, thereby reducing the manufacturing costs of organic EL devices.

The thin-film formation system according to the present invention is not only used for organic EL device manufacturing systems, but also widely applicable to thin-film formation on substrates covered by a deposition mask. For example, the present invention is applicable to a system which uses a sputtering, CVD, or similar process for film formation on substrates covered by a deposition mask.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2010-246381, filed Nov. 2, 2010, which is hereby incorporated by reference herein in its entirety.

What is claimed is:

1. A thin-film formation system comprising:
a first conveying mechanism to convey a substrate and a deposition mask to a substrate carry-in position;
an alignment mechanism placed at the substrate carry-in position and to align the substrate and the deposition mask with each other by moving the substrate and the deposition mask relatively to each other;
a second conveying mechanism to pass the aligned substrate and the deposition mask through a film formation interval;
a film formation mechanism to laminate a layer of organic material on the substrate through an opening in the deposition mask in the film formation interval; and
a third conveying mechanism to convey from a carry-out position the substrate and the deposition mask which have passed the film formation interval,
wherein at least one of the first conveying mechanism and the third conveying mechanism is placed parallel to the second conveying mechanism.

2. The thin-film formation system according to claim 1, further comprising a transfer mechanism to transfer the substrate and the deposition mask from one conveying mechanism to another conveying mechanism, the conveying mechanisms being placed parallel to each other.

3. The thin-film formation system according to claim 1, wherein a speed at which the second conveying mechanism conveys the substrate and the deposition mask is variable.

4. An in-line manufacturing system for organic electroluminescence devices which builds up a layer of organic material while conveying substrates and deposition masks successively in a vacuum environment, the in-line manufacturing system comprising the thin-film formation system according to claim 1 as a film formation chamber.
